(19) United States
(12) Patent Application Publication
(10) Pub. No.: US 2025/0024744 A1
(43) Pub. Date: Jan. 16, 2025

(54) DISPLAY DEVICE

(71) Applicant: Samsung Display Co., Ltd., Yongin-si (KR)

(72) Inventors: HOON KIM, Yongin-si (KR); HAEYOUNG YUN, Yongin-si (KR); WAN NAMGUNG, Yongin-si (KR); DAEWON BAEK, Yongin-si (KR); HEEJIN JEON, Yongin-si (KR)

(21) Appl. No.: 18/638,680

(22) Filed: Apr. 18, 2024

(30) Foreign Application Priority Data
Jul. 10, 2023 (KR) 10-2023-0089149

(51) Int. Cl. H10K 59/80; H10K 59/35

(52) U.S. Cl. CPC H10K 59/8792; H10K 59/352; H10K 59/353

(57) ABSTRACT

A display device includes a display panel including a display area including a first area and a second area adjacent to the first area and a non-display area. The first area includes first pixels, the second area includes second pixels, the first pixels include a first-first pixel, a first-second pixel, and a first-third pixel, the second pixels include a second-first pixel, a second-second pixel, and a second-third pixel, each of the first-first to first-third pixels has an elliptical shape with a first eccentricity value, and each of the second-first to second-third pixels has an elliptical shape with a second eccentricity value.

This U.S. non-provisional patent application claims priority, under 35 U.S.C. § 119, of Korean Patent Application No. 10-2023-0089149 filed on Jul. 10, 2023, the contents of which are hereby incorporated by reference in its entirety.

### BACKGROUND

### 1. Field of Disclosure

The present disclosure relates to a display device. More particularly, the present disclosure relates to a display device including a pixel having an elliptical shape.

### 2. Description of the Related Art

An electronic device includes various electronic parts such as a display panel, an electronic module, and the like. The electronic module includes a camera, an infrared sensor, or a proximity sensor. The electronic module is disposed under the display panel. A portion of the display panel has a transmittance higher than that of other portions of the display panel. The electronic module receives an external input through the portion of the display panel that has higher transmittance or provides an output through the portion of the display panel.

### SUMMARY

The present disclosure provides a display device with improved reflection characteristics by varying an eccentricity of pixels with an elliptical shape for each area.

The present disclosure provides a display device with improved reflection characteristics by varying an eccentricity of pixels with an elliptical shape for each color of the pixels.

The inventive concept pertains to a display device including a display panel including a display area including a first area and a second area adjacent to the first area and a non-display area adjacent to the display area and an anti-reflective layer disposed on the display panel. The first area includes a plurality of first pixels, the second area includes a plurality of second pixels, the first pixels include a first-first pixel emitting a first color light, a first-second pixel emitting a second color light, and a first-third pixel emitting a third color light, the second pixels include a second-first pixel emitting the first color light, a second-second pixel emitting the second color light, and a second-third pixel emitting the third color light, each of the first-first, first-second, and first-third pixels has an elliptical shape having a major axis, a minor axis, and a first eccentricity value, each of the second-first to second-third pixels has an elliptical shape having a major axis, a minor axis, and a second eccentricity value that is lower than the first eccentricity value. A second angle is closer to zero than a first angle, wherein the first angle is an angle between a direction in which the major axis of the first-first pixel extends and a direction in which the major axis of the first-second pixel nearest to the first-first pixel extends. The second angle is an angle between a direction in which the major axis of the second-first pixel extends and a direction in which the major axis of the second-second pixel nearest to the second-first pixel extends.

The first-first pixel may have a size greater than a size of the first-second pixel and a size of the first-third pixel when viewed in a plane, and the second-first pixel may have a size greater than a size of the second-second pixel and a size of the second-third pixel when viewed in the plane.

The first color light may be a blue light, the second color light may be a green light, and a third color light may be a red light.

The first pixels may include a first pixel row and a second pixel row, the first pixel row may include the first-first pixel and the first-third pixel arranged in a first direction, and the second pixel row may include the first-second pixel arranged in the first direction.

The second pixels may include a first pixel row and a second pixel row, the first pixel row may include the second-first pixel and the second-third pixel arranged in a first direction, and the second pixel row may include the second-second pixel arranged in the first direction.

The first angle may be equal to or greater than about 40 degrees and equal to or smaller than about 50 degrees.

The second angle may be about zero (0) degrees.

The first-first pixel and the second-first pixel may have substantially the same size when viewed in a plane.

The anti-reflective layer may include a color filter disposed on the display panel and overlapping the first pixels and the second pixels, a light blocking pattern disposed on the display panel and preventing an external light from being reflected, and a planarization layer covering the color filter and the light blocking pattern and providing a flat upper surface.

A minimum distance between two pixels adjacent to each other among the first-first, first-second, and first-third pixels of each of the first pixels may be substantially equal to a minimum distance between two pixels adjacent to each other among the second-first, second-second, and second-third pixels of each of the second pixels.

A minimum distance between two pixels adjacent to each other among the first-first, first-second, and first-third pixels of each of the first pixels may be equal to or greater than about 18 micrometers.

The first eccentricity value is equal to or greater than about 0.8 and smaller than about 1.

The second eccentricity value is equal to or smaller than about 0.6.

An average of the first eccentricity value and the second eccentricity value may be equal to or greater than about 0.6.

The inventive concept pertains to a display device including a display panel including a display area including a plurality of pixels and a non-display area adjacent to the display area and an anti-reflective layer disposed on the display panel. The pixels include a first pixel emitting a first color light and having an elliptical shape with a first eccentricity value, a second pixel emitting a second color light and having an elliptical shape with a second eccentricity value, and a third pixel emitting a third color light and having an elliptical shape with a third eccentricity value, and the first eccentricity value increases when an angle between a direction in which a major axis of the first pixel extends and a direction in which a major axis of the second pixel nearest to the first pixel extends increases.

The first eccentricity value, the second eccentricity value, and the third eccentricity value may be substantially the same.

The first eccentricity value may be different from at least one of the second eccentricity value and the third eccentricity value.

The first eccentricity value may be greater than the second eccentricity value and the third eccentricity value, and the second eccentricity value and the third eccentricity value are substantially the same.

The first pixel may have a size greater than a size of the second pixel and a size of the third pixel when viewed in a plane.

An average of the first eccentricity value, the second eccentricity value, and the third eccentricity value may be equal to or greater than about 0.6.

According to the above, the minimum separation distance between pixels adjacent to each other may be achieved by varying the eccentricity of the pixels depending on the size of the angle between the extension directions of the major axes of adjacent pixels. Accordingly, the minimum separation distance between adjacent pixels is secured, and reflection characteristics is improved by increasing the eccentricity value of the pixel.

According to the above, the reflection color is improved by varying the eccentricity values of the pixels with the elliptical shape depending on colors of the pixels.

### BRIEF DESCRIPTION OF THE DRAWINGS

The above and other advantages of the present disclosure will become readily apparent by reference to the following detailed description when considered in conjunction with the accompanying drawings wherein:

FIGS. 1A and 1B are perspective views of an electronic device according to an embodiment of the present disclosure;

FIG. 2 is an exploded perspective view of an electronic device according to an embodiment of the present disclosure;

FIG. 3 is a plan view of a display panel according to an embodiment of the present disclosure;

FIG. 4 is a cross-sectional view of a display module according to an embodiment of the present disclosure;

FIG. 5 is a plan view of structures of pixels according to an embodiment of the present disclosure;

FIGS. 6A to 6D are plan views of structures of pixels according to embodiments of the present disclosure;

FIG. 7 is a graph showing a relationship between an angle of a major axis and an eccentricity according to an embodiment of the present disclosure;

FIGS. 8A to 8D are views of reflection characteristics according to an eccentricity of a pixel;

FIGS. 9A and 9B are views of reflection characteristics according to an eccentricity of a pixel; and

FIGS. 10A to 10E are plan views of structures of pixels according to embodiments of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

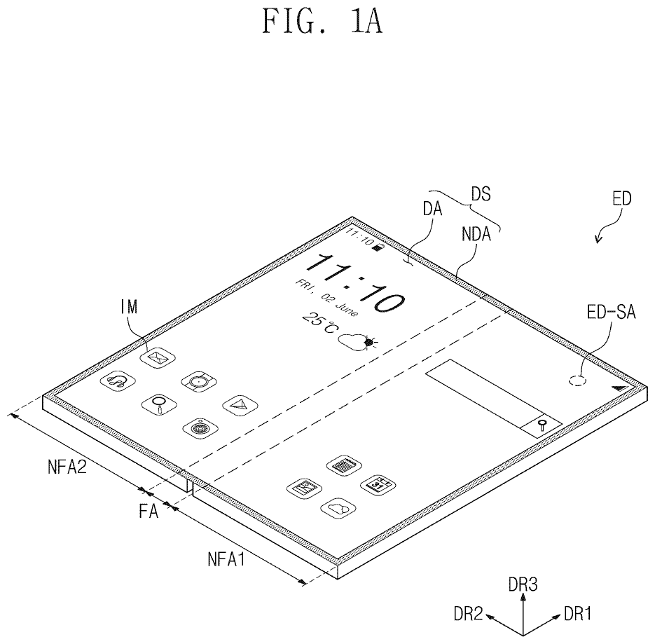

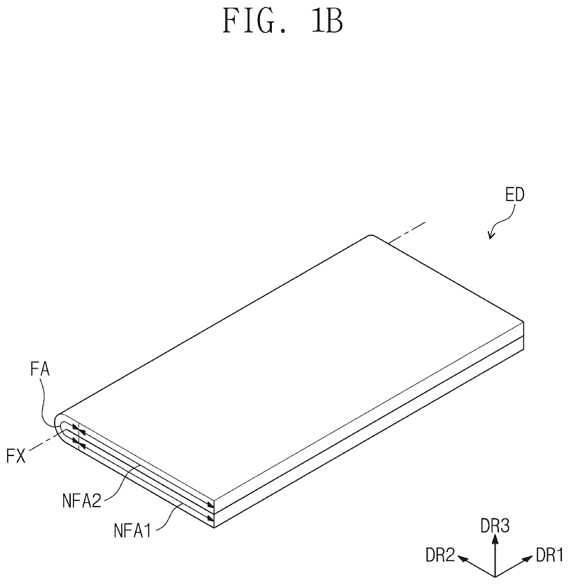

FIGS. 1A and 1B are perspective views of an electronic device ED according to an embodiment of the present disclosure. FIG. 1A shows an unfolded state of the electronic device ED, and FIG. 1B shows a folded state of the electronic device ED.

Referring to FIGS. 1A and 1B, the electronic device ED may include a display surface DS defined by a first direction DR1 and a second direction DR2 intersecting the first direction DR1. The electronic device ED may provide an image IM to a user through the display surface DS.

The display surface DS may include a display area DA and a non-display area NDA around the display area DA. The display area DA may display the image IM, and the non-display area NDA may not display the image IM. The non-display area NDA may surround the display area DA. However, the disclosure is not limited to such arrangement of the display area DA and non-display area NDA, and the shape of the display area DA and the shape and positions of the non-display area NDA may be changed.

Hereinafter, a direction substantially perpendicular to a plane defined by the first direction DR1 and the second direction DR2 may be referred to as a third direction DR3. In the present disclosure, the expression “when viewed in a plane” may mean a state of being viewed in the third direction DR3.

A sensing area ED-SA may be defined in the display area DA of the electronic device ED. FIG. 1A shows one sensing area ED-SA as a representative example; however, the number or position of the sensing areas ED-SA should not be limited to what is shown in FIG. 1A. The sensing area ED-SA may be a portion of the display area DA. Accordingly, the electronic device ED may display the image through the sensing area ED-SA.

The electronic device ED may include an electronic module disposed in an area overlapping the sensing area ED-SA. The electronic module may receive an external input provided from the outside through the sensing area ED-SA or may output a signal through the sensing area ED-SA. For example, the electronic module may be a camera module, a sensor that measures a distance, such as a proximity sensor, a sensor that recognizes a part of a user's body, e.g., a fingerprint, an iris, or a face, or a small lamp that outputs light, however, it the electronic module is not particularly limited to these possibilities. Hereinafter, the camera module will be described as the electronic module overlapping the sensing area ED-SA.

The electronic device ED may include a folding area FA and a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2 in the second direction DR2. The folding area FA may be referred to as a foldable area, and the first and second non-folding areas NFA1 and NFA2 may be referred to as first and second non-foldable areas, respectively.

As shown in FIG. 1B, the folding area FA may be folded with respect to a folding axis FX substantially parallel to the first direction DR1. The folding area FA may have a predetermined curvature and a radius of curvature when the electronic device ED is in the folded state. The electronic device ED may be folded inwardly (inner-folding) such that the first non-folding area NFA1 faces the second non-folding area NFA2 and the display surface DS is not showing on the outside of the folded device.

According to an embodiment, the electronic device ED may be folded outwardly such that the display surface DS shows on the outside in the folded state. According to an embodiment, the electronic device ED may be provided such that the inner-folding operation or the outer-folding operation and unfolding operation is repeated. According to an embodiment, the electronic device ED may be provided to carry out any one of the unfolding operation, the inner-folding operation, and the outer-folding operation.

FIGS. 1A and 1B show the foldable electronic device ED as a representative example. However, the present disclosure should not be limited to the foldable electronic device ED. For example, the present disclosure may be applied to a rigid electronic device, e.g., an electronic device that does not include the folding area FA.

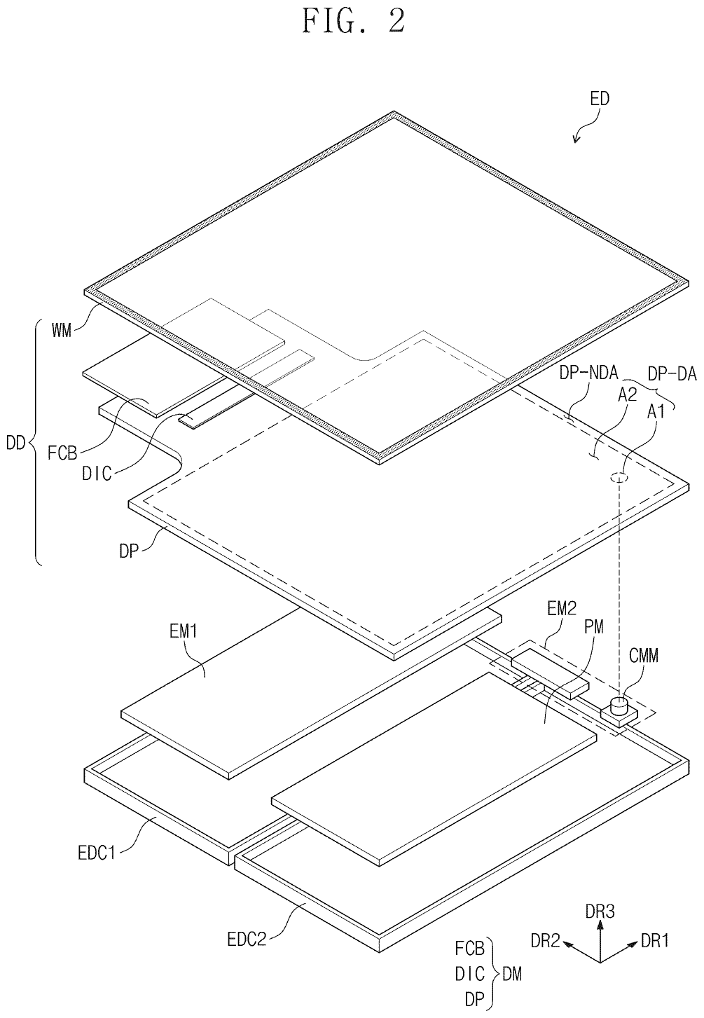

FIG. 2 is an exploded perspective view of the electronic device ED according to an embodiment of the present disclosure.

Referring to FIG. 2, the electronic device ED may include a display device DD, a first electronic module EM1, a second electronic module EM2, a power supply module PM, and housings EDC1 and EDC2. Although not shown in figures, the electronic device ED may further include a mechanical structure to control a folding operation of the display device DD.

The display device DD may include a window module WM and a display module DM. The window module WM may provide a front surface of the electronic device ED. The display module DM may include at least a display panel DP. The display module DM may generate the image and may sense an external input.

Although the display module DM is shown to be the same as the display panel DP in FIG. 2, the display module DM may have a stacked structure in which plural components including the display panel DP are stacked on one on another. Detailed descriptions on the stacked structure of the display module DM will be described below.

The display panel DP may include a display area DP-DA and a non-display area DP-NDA, which respectively correspond to the display area DA (refer to FIG. 1A) and the non-display area NDA (refer to FIG. 1A) of the electronic device ED. In the present disclosure, the expression “An area/portion corresponds to another area/portion.” means that “An area/portion overlaps another area/portion.”, however, the “areas and portions” should not be limited to have the same size as each other.

The display area DP-DA may include a first area A1 and a second area A2. The first area A1 may overlap or correspond to the sensing area ED-SA (refer to FIG. 1A) of the electronic device ED. In the present embodiment, the first area A1 is shown as a circular shape, however, the shape of the first area A1 should not be limited to what is depicted in FIG. 2. The first area A1 may have a variety of shapes, such as a polygonal shape, an elliptical shape, a figure having at least one curved side, or an irregular shape. The first area A1 may be referred to as a component area, and the second area A2 may be referred to as a main display area or a normal display area.

The first area A1 may have a transmittance higher than that of the second area A2. In addition, the first area A1 may have a resolution lower than that of the second area A2. The first area A1 may overlap a camera module CMM described below.

The display module DM may include a driving chip DIC disposed in the non-display area DP-NDA. The display module DM may further include a flexible circuit film FCB coupled with the display panel DP in the non-display area DP-NDA.

The driving chip DIC may include driving elements, e.g., a data driving circuit, to drive pixels of the display panel DP. FIG. 2 shows a structure in which the driving chip DIC is mounted on the display panel DP. However, the present disclosure should not be limited by the examples. In some embodiments, the driving chip DIC may be mounted on the flexible circuit film FCB.

The power supply module PM may supply a power source necessary for an overall operation of the electronic device ED. The power supply module PM may include a well-known battery module.

The first electronic module EM1 and the second electronic module EM2 may include a variety of functional modules to drive the electronic device ED. Each of the first electronic module EM1 and the second electronic module EM2 may be mounted directly on a mother board, which is electrically connected to the display panel DP, or may be electrically connected to the mother board via a connector (not shown) after being mounted on a separate substrate.

The first electronic module EM1 and the second electronic module EM2 may include various components to control an overall operation of the electronic device ED. For example, the first electronic module EM1 may include a control module, a wireless communication module, an image input module, an audio input module, a memory, and an external interface. The second electronic module EM2 may include an audio output module, a light emitting module, a light receiving module, and a camera module.

The housings EDC1 and EDC2 may accommodate the display module DM, the first and second electronic modules EM1 and EM2, and the power supply module PM. The housings EDC1 and EDC2 may protect components accommodated therein, e.g., the display module DM, the first and second electronic modules EM1 and EM2, and the power supply module PM. FIG. 2 shows two housings EDC1 and EDC2 separated from each other as a representative example. However, the present disclosure should not be limited by the embodiments. Although not shown in figures, the electronic device ED may further include a hinge structure to connect the two housings EDC1 and EDC2. The housings EDC1 and EDC2 may be coupled with the window module WM.

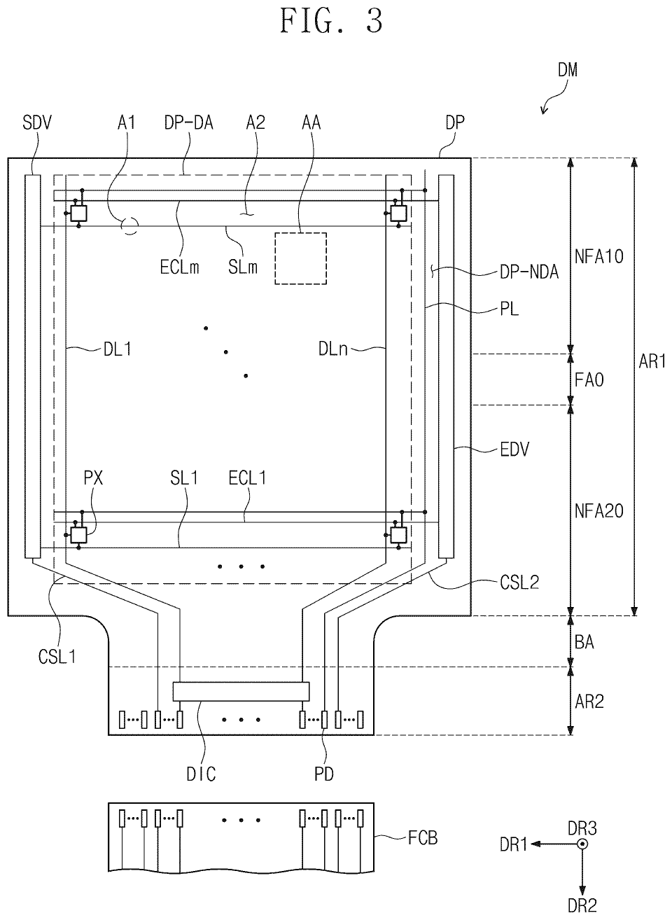

FIG. 3 is a plan view of the display panel DP according to an embodiment of the present disclosure.

Referring to FIG. 3, the display panel DP may include the display area DP-DA and the non-display area DP-NDA around the display area DP-DA. The display area DP-DA and the non-display area DP-NDA may be distinguished from each other by a presence or absence of a pixel PX. The pixel PX may be disposed in the display area DP-DA. A scan driver SDV, a data driver, and an emission driver EDV may be disposed in the non-display area NDA. The data driver may be a circuit provided in the driving chip DIC.

The display area DP-DA may include the first area A1 and the second area A2. The first area A1 and the second area A2 may be distinguished from each other by an arrangement interval of the pixels PX, a size of the pixels PX, or the like.

The display panel DP may include a first panel area AR1, a bending area BA, and a second panel area AR2, which are defined in the second direction DR2. The second panel area AR2 and the bending area BA may be areas of the non-display area DP-NDA. The bending area BA may be defined between the first panel area AR1 and the second panel area AR2.

The first panel area AR1 may correspond to the display surface DS of FIG. 1A. The first panel area AR1 may include a first non-folding area NFA10, a second non-folding area NFA20, and a folding area FAO. The first non-folding area NFA10, the second non-folding area NFA20, and the folding area FAO may respectively correspond to the first non-folding area NFA1, the second non-folding area NFA2, and the folding area FA of FIGS. 1A and 1B.

The bending area BA may be an area that is bent when the electronic device ED is assembled. As the display panel DP includes the bending area BA, the electronic device having a narrow bezel may be easily implemented.

A width (or a length) in the first direction DR1 of the bending area BA and a width (or a length) in the first direction DR1 of the second panel area AR2 may be smaller than a width (or a length) in the first direction DR1 of the first panel area AR1. An area having a relatively short length in a bending axis direction may be relatively easily bent.

The display panel DP may include a plurality of pixels PX, a plurality of scan lines SL1 to SLm, a plurality of data lines DL1 to DLn, a plurality of emission control lines ECL1 to ECLm, first and second control lines CSL1 and CSL2, a driving voltage line PL, and a plurality of pads PD. In the present embodiment, each of “m” and “n” is a natural number. The pixels PX may be connected to the scan lines SL1 to SLm, the data lines DL1 to DLn, and the emission control lines ECL1 to ECLm.

The scan lines SL1 to SLm may extend in the first direction DR1 and may be electrically connected to the scan driver SDV. The data lines DL1 to DLn may extend in the second direction DR2 and may be electrically connected to the driving chip DIC via the bending area BA. The emission control lines ECL1 to ECLm may extend in a direction opposite to the first direction DR1 and may be electrically connected to the emission driver EDV.

The driving voltage line PL may include a portion extending in the first direction DR1 and a portion extending in the second direction DR2. The portion extending in the first direction DR1 and the portion extending in the second direction DR2 may be disposed on different layers from each other. The driving voltage line PL may extend to the second panel area AR2 via the bending area BA. The driving voltage line PL may provide a first voltage to the pixels PX.

The first control line CSL1 may be connected to the scan driver SDV and may extend to a lower end of the second panel area AR2 via the bending area BA. The second control line CSL2 may be connected to the emission driver EDV and may extend to the lower end of the second panel area AR2 via the bending area BA.

When viewed in a plane, the pads PD may be disposed adjacent to the lower end of the second panel area AR2. The driving chip DIC, the driving voltage line PL, the first control line CSL1, and the second control line CSL2 may be electrically connected to the pads PD. The flexible circuit film FCB may be electrically connected to the pads PD through an anisotropic conductive adhesive layer.

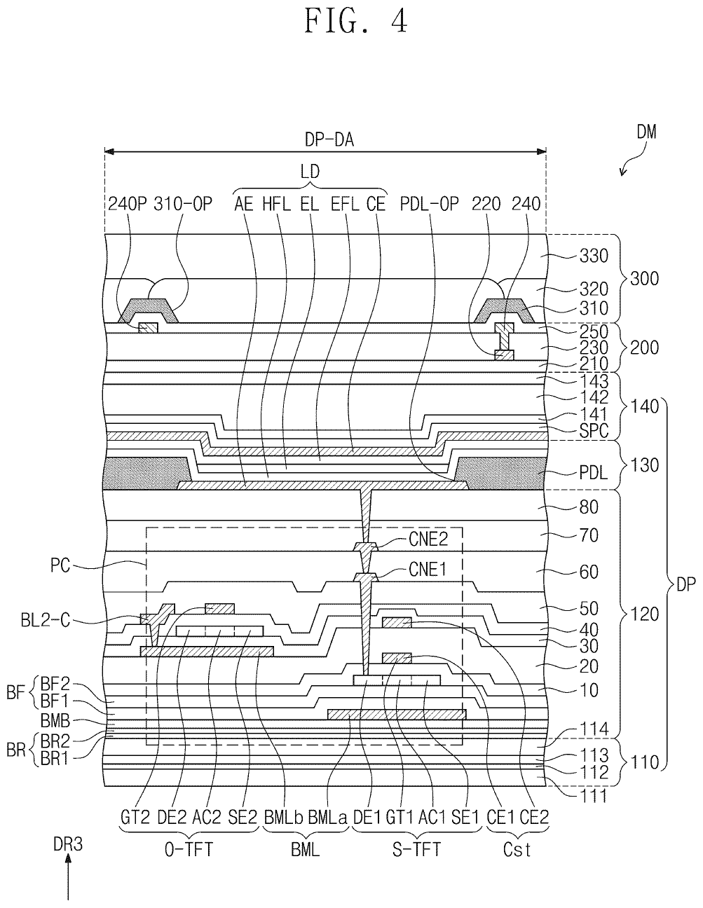

FIG. 4 is a cross-sectional view of the display module DM according to an embodiment of the present disclosure.

Referring to FIG. 4, the display module DM may include the display panel DP, a sensor layer 200, and an anti-reflective layer 300. The display panel DP may include a substrate 110, a circuit layer 120, a light emitting element layer 130, and an encapsulation layer 140.

The display panel DP may have a configuration that substantially generates the image. The display panel DP may be a light emitting type display layer. For example, the display panel DP may be an organic light emitting display layer, an inorganic light emitting display layer, an organic-inorganic light emitting display layer, a quantum dot display layer, a micro-LED display layer, or a nano-LED display layer.

The substrate 110 may include a plurality of layers 111, 112, 113, and 114. For example, the substrate 110 may include a first sub-base layer 111, a first intermediate barrier layer 112, a second intermediate barrier layer 113, and a second sub-base layer 114. The first sub-base layer 111, the first intermediate barrier layer 112, the second intermediate barrier layer 113, and the second sub-base layer 114 may be sequentially stacked in the third direction DR3.

Each of the first sub-base layer 111 and the second sub-base layer 114 may include at least one of a polyimide-based resin, an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. Meanwhile, in the present disclosure, the term “A-based resin” means that a functional group of “A” is included. A barrier layer BR may be disposed on the substrate 110. The barrier layer BR may include a first sub-barrier layer BR1 disposed on the substrate 110 and a second sub-barrier layer BR2 disposed on the first sub-barrier layer BR1.

Each of the first and second intermediate barrier layers 112 and 113 and each of the first and second sub-barrier layers BR1 and BR2 may include an inorganic material. Each of the first and second intermediate barrier layers 112 and 113 and each of the first and second sub-barrier layers BR1 and BR2 may include at least one of silicon oxide, silicon nitride, silicon oxynitride, and amorphous silicon. For example, each of the first and second sub-base layers 111 and 114 may include polyimide having a refractive index of about 1.9. The first intermediate barrier layer 112 and the first sub-barrier layer BR1 may include silicon oxynitride (SiON) having a refractive index of about 1.72. The second intermediate barrier layer 113 and the second sub-barrier layer BR2 may include silicon oxide (SiOx) having a refractive index of about 1.5.

That is, the refractive index of the first intermediate barrier layer 112 may have a value between the refractive index of the first sub-base layer 111 and the refractive index of the second intermediate barrier layer 113. The refractive index of the first sub-barrier layer BR1 may have a value between the refractive index of the second sub-base layer 114 and the refractive index of the second sub-barrier layer BR2. As a difference in refractive index between layers that are in contact with each other decreases, a reflection of a light at an interface between the layers that are in contact with each other may be reduced.

The first sub-base layer 111 may be thicker than a the second sub-base layer 114. However, the thickness of each of the first and second sub-base layers 111 and 114 should not be limited by the example embodiments. The first intermediate barrier layer 112 may be thinner than the second intermediate barrier layer 113, and the first sub-barrier layer BR1 may be thinner than the second sub-barrier layer BR2. However, the thickness of the first and second intermediate barrier layers 112 and 113 and the first and second sub-barrier layers BR1 and BR2 should not be limited by the examples in this disclosure.

A light blocking layer BML may be disposed on the barrier layer BR. The light blocking layer BML may include a first light blocking layer BMLa and a second light blocking layer BMLb. The light blocking layer BML may include molybdenum (Mo), an alloy including molybdenum (Mo), silver (Ag), an alloy including silver (Ag), aluminum (Al), an alloy including aluminum (Al), aluminum nitride (AlN), tungsten (W), tungsten nitride (WN), copper (Cu), titanium Ti, p+ doped amorphous silicon, MoTaOx, or the like; however, this is not an exhaustive list and the disclosure should not be limited by these examples. The light blocking layer BML may be referred to as a rear surface metal layer or a rear surface layer.

At least one lower insulating layer BMB may be disposed between the light blocking layer BML and the barrier layer BR. The lower insulating layers BMB may include an inorganic material. For example, the lower insulating layers BMB may include at least one of silicon oxide, silicon nitride, silicon oxynitride, and amorphous silicon.

A buffer layer BF may be disposed on the lower insulating layer BMB and the barrier layer BR. The buffer layer BF may prevent metal atoms or impurities from being diffused to a first semiconductor pattern from the substrate 110. In addition, the buffer layer BF may control a rate of heat supply during a crystallization process to form the first semiconductor pattern so that the first semiconductor pattern may be uniformly formed.

The buffer layer BF may include a first sub-buffer layer BF1 and a second sub-buffer layer BF2 disposed on the first sub-buffer layer BF1. Each of the first sub-buffer layer BF1 and the second sub-buffer layer BF2 may include at least one of silicon oxide, silicon nitride, and silicon oxynitride. For example, the first sub-buffer layer BF1 may include silicon nitride, and the second sub-buffer layer BF2 may include silicon oxide.

Each of the pixels PX (refer to FIG. 3) may include a light emitting element LD and a pixel circuit PC. The pixel circuit PC may include a silicon thin film transistor S-TFT and an oxide thin film transistor O-TFT.

The first light blocking layer BMLa may be disposed under the silicon thin film transistor S-TFT, and the second light blocking layer BMLb may be disposed under the oxide thin film transistor O-TFT. Each of the first light blocking layer BMLa and the second light blocking layer BMLb may be disposed to overlap the pixel circuit PC to protect the pixel circuit PC.

The first and second light blocking layers BMLa and BMLb may prevent an electric potential caused by a polarization phenomenon of the first sub-base layer 111 or the second sub-base layer 114 from exerting influence on the pixel circuit PC. According to an embodiment, the second light blocking layer BMLb may be omitted.

In the present embodiment, the first light blocking layer BMLa may be disposed under the lower insulating layer BMB. Meanwhile, the first light blocking layer BMLa may be disposed in the second sub-barrier layer BR2. For example, a portion in a thickness direction of the second sub-barrier layer BR2 is formed, and the first light blocking layer BMLa is formed thereon. Then, the other portion in the thickness direction of the second sub-barrier layer BR2 may be formed to cover the first light blocking layer BMLa. However, this is merely an example, and the first light blocking layer BMLa may be disposed at various positions.

The second light blocking layer BMLb may be disposed between a second insulating layer 20 and a third insulating layer 30. The second light blocking layer BMLb may be disposed on the same layer as a second electrode CE2 of a storage capacitor Cst. The second light blocking layer BMLb may be connected to a contact electrode BL2-C to receive a constant voltage or a signal. The contact electrode BL2-C may be disposed on the same layer as a gate GT2 of the oxide thin film transistor O-TFT. The first and second light blocking layers BMLa and BMLb may include the same material as or different materials from each other. However, this is merely an example. According to an embodiment, the contact electrode BL2-C may be disposed on the same layer as a first connection electrode CNE1 or a second connection electrode CNE2 described below. However, it should not be particularly limited.

The first semiconductor pattern may be disposed on the buffer layer BF. The first semiconductor pattern may include a silicon semiconductor. For example, the silicon semiconductor may include amorphous silicon or polycrystalline silicon. For example, the first semiconductor pattern may include low temperature polycrystalline silicon.

The first semiconductor pattern may have different electrical properties depending on whether it is doped or not or whether it is doped with an N-type dopant or a P-type dopant. The first semiconductor pattern may include a first region having a relatively high conductivity and a second region having a relatively low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or a region doped at a concentration lower than that of the first region.

The first region may have a conductivity greater than that of the second region and may substantially serve as an electrode or signal line. The second region may substantially correspond to an active area (or a channel) of a transistor. In other words, a portion of the first semiconductor pattern may be the active area of the transistor, another portion of the first semiconductor pattern may be a source or a drain of the transistor, and the other portion of the first semiconductor pattern may be a connection electrode or a connection signal line.

A source area SE1, an active area AC1, and a drain area DE1 of the silicon thin film transistor S-TFT may be formed from the first semiconductor pattern. The source area SE1 and the drain area DE1 may extend in opposite directions to each other from the active area AC1 in a cross-section.

The circuit layer 120 may include a plurality of inorganic insulating layers disposed on the light blocking layer BML. According to an embodiment, some of first, second, third, fourth, and fifth insulating layers 10, 20, 30, 40, and 50 sequentially stacked on the buffer layer BF may be inorganic insulating layers. For example, all the first to fifth insulating layers 10 to 50 may be the inorganic insulating layers.

The first insulating layer 10 may be disposed on the buffer layer BF. The first insulating layer 10 may commonly overlap the pixels and may cover the first semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon nitride, silicon oxynitride, zirconium oxide, and hafnium oxide. In the present embodiment, the first insulating layer 10 may have a single-layer structure of a silicon oxide layer. Not only the first insulating layer 10, but also insulating layers of the circuit layer 120 described below may have a single-layer or multi-layer structure.

A gate GT1 of the silicon thin film transistor S-TFT may be disposed on the first insulating layer 10. The gate GT1 may be a portion of a metal pattern. The gate GT1 may overlap the active area AC1. The gate GT1 may be used as a mask in a process of doping the first semiconductor pattern. The gate GT1 may include titanium (Ti), silver (Ag), an alloy including silver (Ag), molybdenum (Mo), an alloy including molybdenum (Mo), aluminum (Al), an alloy including aluminum (Al), aluminum nitride (AlN), tungsten (W), tungsten nitride (WN), copper (Cu), indium tin oxide (ITO), indium zinc oxide (IZO), or the like, however, it should not be particularly limited.

The second insulating layer 20 may be disposed on the first insulating layer 10 and may cover the gate GT1. The second insulating layer 20 may be an inorganic layer and may have a single-layer or multi-layer structure. The second insulating layer 20 may include at least one of silicon oxide, silicon nitride, and silicon oxynitride. According to the present embodiment, the second insulating layer 20 may have the multi-layer structure of a silicon oxide layer and a silicon nitride layer.

The third insulating layer 30 may be disposed on the second insulating layer 20. The third insulating layer 30 may be an inorganic layer and may have a single-layer or multi-layer structure. For example, the third insulating layer 30 may have the multi-layer structure of a silicon oxide layer and a silicon nitride layer. The second electrode CE2 of the storage capacitor Cst may be disposed between the second insulating layer 20 and the third insulating layer 30. In addition, a first electrode CE1 of the storage capacitor Cst may be disposed between the first insulating layer 10 and the second insulating layer 20.

A second semiconductor pattern may be disposed on the third insulating layer 30. The second semiconductor pattern may include an oxide semiconductor. The oxide semiconductor may include a plurality of areas that are distinguishable from each other based on whether a metal oxide is reduced. The area (hereinafter, referred to as a “reduced area”) in which the metal oxide is reduced has a conductivity greater than that of the area (hereinafter, referred to as a non-reduced area) in which the metal oxide is not reduced. The reduced area may act as the source/drain of the transistor or the signal line. The non-reduced area may substantially correspond to the active area (or a semiconductor area, or a channel) of the transistor. In other words, a portion of the second semiconductor pattern may be the active area of the transistor, another portion of the second semiconductor pattern may be the source/drain areas of the transistor, and the other portion of the second semiconductor pattern may be a signal transmission area.

A source area SE2, an active area AC2, and a drain area DE2 of the oxide thin film transistor O-TFT may be formed from the second semiconductor pattern. The source area SE2 and the drain area DE2 may extend in opposite directions to each other from the active area AC2 in a cross-section.

The fourth insulating layer 40 may be disposed on the third insulating layer 30. The fourth insulating layer 40 may commonly overlap the pixels and may cover the second semiconductor pattern. The fourth insulating layer 40 may be an inorganic layer and may have a single-layer or multi-layer structure. The fourth insulating layer 40 may include at least one of aluminum oxide, titanium oxide, silicon oxide, silicon nitride, silicon oxynitride, zirconium oxide, and hafnium oxide.

The gate GT2 of the oxide thin film transistor O-TFT may be disposed on the fourth insulating layer 40. The gate GT2 may be a portion of a metal pattern. The gate GT2 may overlap the active area AC2. The gate GT2 may be used as a mask in a process of doping the second semiconductor pattern.

The fifth insulating layer 50 may be disposed on the fourth insulating layer 40 and may cover the gate GT2. The fifth insulating layer 50 may be an inorganic layer and/or an organic layer and may have a single-layer or multi-layer structure.

The first connection electrode CNE1 may be disposed on the fifth insulating layer 50. The first connection electrode CNE1 may be connected to the drain area DE1 of the silicon thin film transistor S-TFT via a contact hole defined through the first to fifth insulating layers 10 to 50. Meanwhile, although not shown in FIG. 4, the display panel DP may further include a connection electrode that is formed in an area corresponding to the first connection electrode CNE1 and connected to the drain area DE2 or the source area SE2 of the oxide thin film transistor O-TFT, however, the present disclosure should not be limited by the examples.

The circuit layer 120 may include a plurality of organic insulating layers disposed on the inorganic insulating layers. For example, at least one of sixth, seventh, and eighth insulating layers 60, 70, and 80 may be an organic insulating layer.

The sixth insulating layer 60 may be disposed on the fifth insulating layer 50. The sixth insulating layer 60 may include an organic material. For example, the sixth insulating layer 60 may include a polyimide-based resin. The second connection electrode CNE2 may be disposed on the sixth insulating layer 60. The second connection electrode CNE2 may be connected to the first connection electrode CNE1 through a contact hole defined through the sixth insulating layer 60.

The seventh insulating layer 70 may be disposed on the sixth insulating layer 60 and may cover the second connection electrode CNE2. The eighth insulating layer 80 may be disposed on the seventh insulating layer 70.

Each of the sixth insulating layer 60, the seventh insulating layer 70, and the eighth insulating layer 80 may be an organic layer. In the following descriptions, the sixth insulating layer 60, the seventh insulating layer 70, and the eighth insulating layer 80 may be referred to as first, second, and third organic insulating layers, respectively. For example, each of the sixth insulating layer 60, the seventh insulating layer 70, and the eighth insulating layer 80 may include a general-purpose polymer, such as benzocyclobutene (BCB), polyimide, hexamethyldisiloxane (HMDSO), polymethylmethacrylate (PMMA), or polystyrene (PS), a polymer derivative having a phenolic group, an acrylic-based polymer, an imide-based polymer, an aryl ether-based polymer, an amide-based polymer, and a fluorine-based polymer, a p-xylene-based polymer, a vinyl alcohol-based polymer, or blends thereof.

The light emitting element layer 130 including the light emitting element LD may be disposed on the circuit layer 120. The light emitting element LD may include a pixel electrode AE, a first functional layer HFL, a light emitting layer EL, a second functional layer EFL, and a common electrode CE. The first functional layer HFL, the second functional layer EFL, and the common electrode CE may be connected to the pixels PX (refer to FIG. 3) and may be commonly provided.

The pixel electrode AE may be disposed on the eighth insulating layer 80. The pixel electrode AE may be a semi-transmissive electrode, a transmissive electrode, or a reflective electrode. According to an embodiment, the pixel electrode AE may include a reflective layer formed of Ag, Mg, Al, Pt, Pd, Au, Ni, Nd, Ir, Cr, or compounds thereof and a transparent or semi-transparent electrode layer formed on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO), indium oxide (In₂O₃), and aluminum-doped zinc oxide (AZO). For instance, the pixel electrode AE may have a stack structure of ITO/Ag/ITO.

In the present embodiment, the pixel electrode AE is connected to the silicon thin film transistor S-TFT via the first connection electrode CNE1 and the second connection electrode CNE2. However, the present disclosure should not be limited by the example embodiment. According to an embodiment, the pixel electrode AE may be connected to the oxide thin film transistor O-TFT, and it should not be particularly limited.

A pixel definition layer PDL may be disposed on the eighth insulating layer 80. The pixel definition layer PDL may have a light absorbing property, for example, the pixel definition layer PDL may have a black color. The pixel definition layer PDL may include a black coloring agent. The black coloring agent may include a black dye or a black pigment. The black coloring agent may include a metal material, such as carbon black, chromium, or an oxide thereof.

The pixel definition layer PDL may be provided with an opening PDL-OP defined therethrough to a portion of the pixel electrode AE. The pixel definition layer PDL may cover an edge of the pixel electrode AE.

The first functional layer HFL may be disposed on the pixel electrode AE and the pixel definition layer PDL. The first functional layer HFL may include a hole transport layer, may include a hole injection layer, or may include both the hole transport layer and the hole injection layer.

The light emitting layer EL may be disposed on the first functional layer HFL and may be disposed in an area corresponding to the opening PDL-OP of the pixel definition layer PDL. The light emitting layer EL may include an organic material, an inorganic material, or an organic-inorganic material which emits a light having a predetermined color. The light emitting layer EL may be disposed in the display area DP-DA.

The second functional layer EFL may be disposed on the first functional layer HFL and may cover the light emitting layer EL. The second functional layer EFL may include an electron transport layer, may include an electron injection layer, or may include both the electron transport layer and the electron injection layer.

The common electrode CE may be disposed on the second functional layer EFL. The light emitting element layer 130 may further include a capping layer SPC disposed on the common electrode CE. The capping layer SPC may include LiF, an inorganic material, and/or an organic material.

The encapsulation layer 140 may be disposed on the light emitting element layer 130. The encapsulation layer 140 may include an inorganic layer 141, an organic layer 142, and an inorganic layer 143, which are sequentially stacked. However, layers included in the encapsulation layer 140 should not be limited by the example embodiments.

The inorganic layers 141 and 143 may protect the light emitting element layer 130 from moisture and oxygen, and the organic layer 142 may protect the light emitting element layer 130 from a foreign substance such as dust particles. The inorganic layers 141 and 143 may include a silicon nitride layer, a silicon oxynitride layer, a silicon oxide layer, a titanium oxide layer, or an aluminum oxide layer. The organic layer 142 may include an acrylic-based organic layer. However, the organic layers should not be limited by the example embodiments.

The sensor layer 200 may be disposed on the display panel DP. The sensor layer 200 may sense an external input applied from the outside. For example, the external input may be a user input. The user input may include a variety of external inputs, such as a part of user's body, light, heat, pen, or pressure.

The sensor layer 200 may be referred to as a sensor, an input sensing layer, or an input sensing panel. The sensor layer 200 may include a sensor base layer 210, a first sensor conductive layer 220, a sensor insulating layer 230, a second sensor conductive layer 240, and a sensor cover layer 250.

The sensor base layer 210 may be disposed directly on the display panel DP. The sensor base layer 210 may be an inorganic layer including at least one of silicon nitride, silicon oxynitride, and silicon oxide. According to an embodiment, the sensor base layer 210 may be an organic layer including an epoxy resin, an acrylic resin, or an imide-based resin. The sensor base layer 210 may have a single-layer structure or a multi-layer structure of layers stacked in the third direction DR3.

Each of the first sensor conductive layer 220 and the second sensor conductive layer 240 may have a single-layer structure or a multi-layer structure of layers stacked in the third direction DR3.

The conductive layer having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), indium zinc tin oxide (ITZO), or the like. In addition, the transparent conductive layer may include conductive polymer such as PEDOT, metal nanowire, graphene, or the like.

The conductive layer having the multi-layer structure may include metal layers. The metal layers may have a three-layer structure of titanium/aluminum/titanium. The conductive layer having the multi-layer structure may include at least one metal layer and at least one transparent conductive layer.

The sensor insulating layer 230 may be disposed between the first sensor conductive layer 220 and the second sensor conductive layer 240. The sensor insulating layer 230 may include an inorganic layer. The inorganic layer may include at least one of aluminum oxide, titanium oxide, silicon oxide, silicon nitride, silicon oxynitride, zirconium oxide, and hafnium oxide.

According to an embodiment, the sensor insulating layer 230 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The sensor cover layer 250 may be disposed on the sensor insulating layer 230 and may cover the second sensor conductive layer 240. The sensor cover layer 250 may include an inorganic material. For example, the sensor cover layer 250 may include silicon nitride. However, that is not a limitation of the disclosure.

The anti-reflective layer 300 may be disposed on the sensor layer 200. The anti-reflective layer 300 may include a light blocking pattern 310, a plurality of color filters 320, and a planarization layer 330.

The light blocking pattern 310 may be disposed on the display panel DP and may overlap the second sensor conductive layer 240. The sensor cover layer 250 may be disposed between the light blocking pattern 310 and the second sensor conductive layer 240. The light blocking pattern 310 may prevent an external light from being reflected by the second sensor conductive layer 240. Materials for the light blocking pattern 310 should not be particularly limited as long as the materials absorb light. The light blocking pattern 310 may have a black color and may have a black coloring agent. The black coloring agent may include a black dye or a black pigment. The black coloring agent may include a metal material, such as carbon black, chromium, or an oxide thereof.

The light blocking pattern 310 may be provided with a plurality of division openings 310-OP defined therethrough. The division openings 310-OP may overlap the light emitting layers EL, respectively.

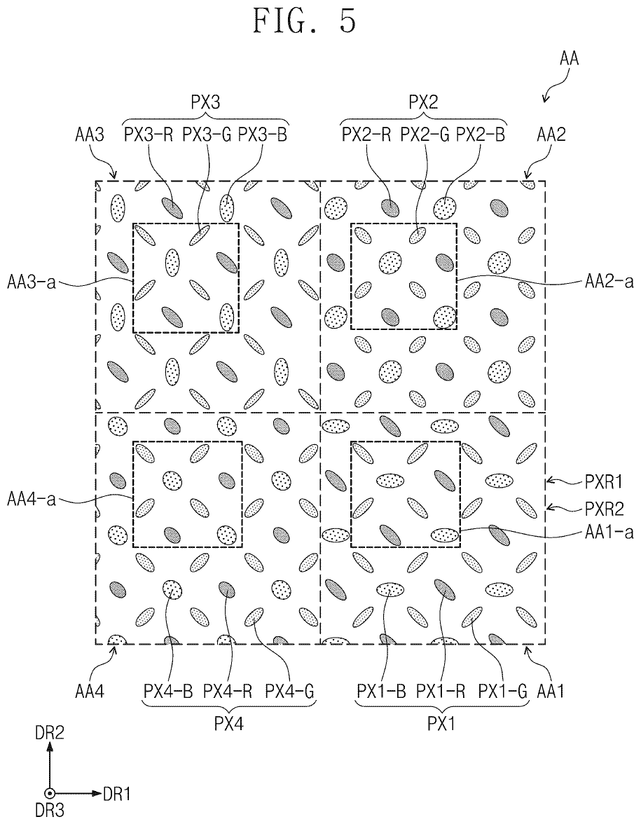

The color filters 320 may be disposed on the display panel DP and may be disposed to correspond to the division openings 310-OP, respectively. The color filters 320 may overlap first to fourth pixels PX1 to PX4 (refer to FIG. 5). The color filters 320 may transmit a light provided from the light emitting layer EL overlapping the color filters 320.

The planarization layer 330 may cover the light blocking pattern 310 and the color filters 320. The planarization layer 330 may include an organic material and may provide a flat surface on an upper surface thereof. According to an embodiment, the planarization layer 330 may be omitted.

FIG. 5 is a plan view of structures of pixels according to an embodiment of the present disclosure. In more detail, FIG. 5 is an enlarged plan view of an area AA of FIG. 3.

Referring to FIG. 5, the display area DP-DA of the display panel DP (refer to FIG. 3) may include a first area AA1, a second area AA2, a third area AA3, and a fourth area AA4. The first area AA1 may include a plurality of first pixels PX1. The second area AA2 may include a plurality of second pixels PX2. The third area AA3 may include a plurality of third pixels PX3. The fourth area AA4 may include a plurality of fourth pixels PX4.

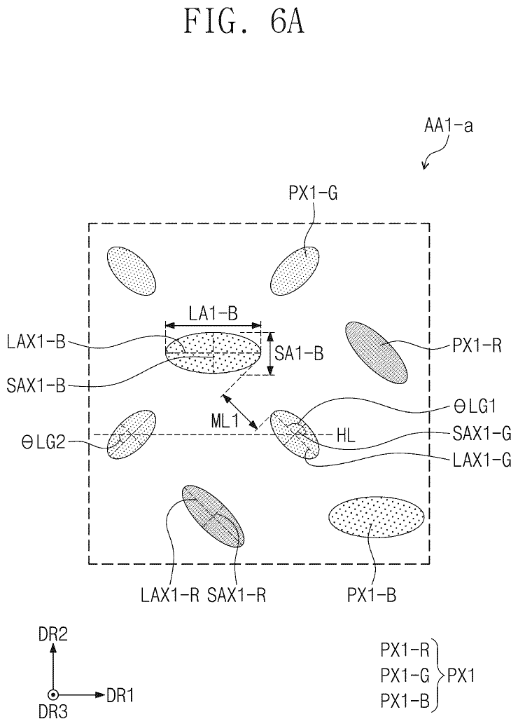

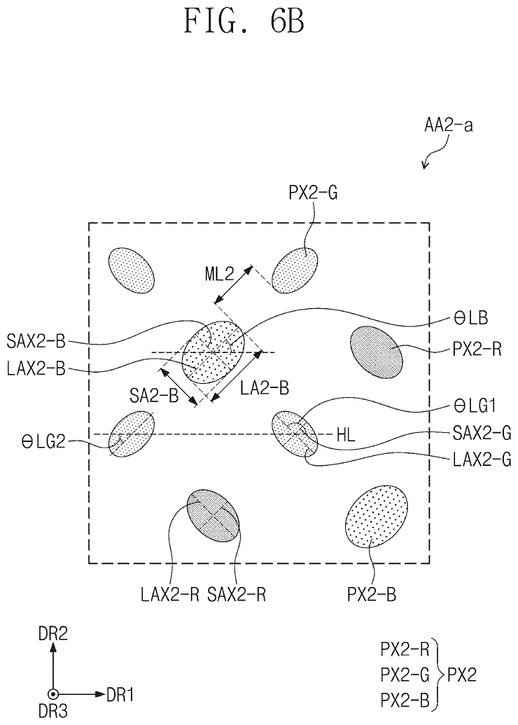

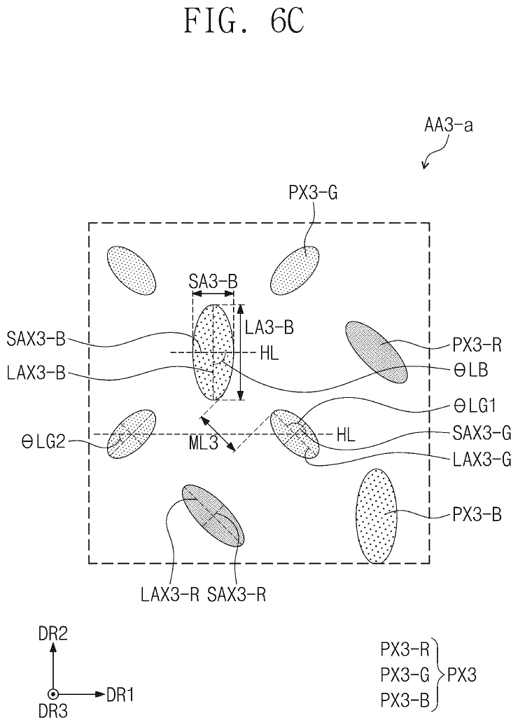

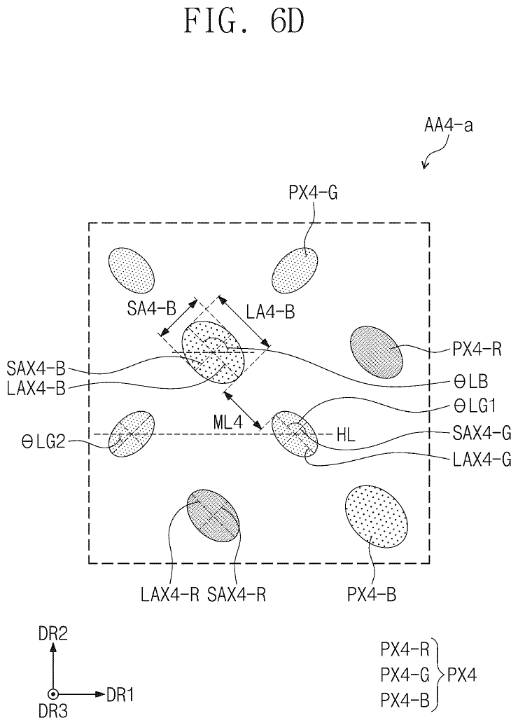

Each of the first to fourth pixels PX1 to PX4 may include a plurality of pixels each having an elliptical shape with major and minor axes. In this case, the first to fourth pixels PX1 to PX4 may have the same eccentricity or different eccentricities. This will be described in detail with reference to FIGS. 6A to 6D.

The first area AA1 may include the first pixels PX1. The first pixels PX1 may include a first-first pixel PX1-B emitting a first color light, a first-second pixel PX1-G emitting a second color light, and a first-third pixel PX1-R emitting a third color light. In the present embodiment, the first color light may be a blue color light, the second color light may be a green color light, and the third color light may be a red color light. However, colors of first, second, and third color lights should not be limited by the examples in this disclosure. For example, the first, second, and third color lights may be red, green, and blue color lights, respectively.

The first pixels PX1 may include a first pixel row PXR1 and a second pixel row PXR2. The first pixel row PXR1 may include a first-first pixel PX1-B and a first-third pixel PX1-R, which are arranged in the first direction DR1. In the first pixel row PXR1, the first-first pixel PX1-B and the first-third pixel PX1-R may be alternately arranged with each other. The second pixel row PXR2 may include first-second pixels PX1-G arranged in the first direction DR1. In this case, the first-second pixel PX1-G may be disposed between the first-first pixel PX1-B and the first-third pixel PX1-R in the first direction DR1.

Each of the first pixel row PXR1 and the second pixel row PXR2 may be provided in plural, and the first pixel rows PXR1 may be alternately arranged with the second pixel rows PXR2 in the second direction DR2. Four first-second pixels PX1-G may surround one first-first pixel PX1-B. The arrangement structure of the pixels in the first area AA1 may be the same as that in the second area AA2 to the fourth area AA4. That is, each of the second pixels PX2 to the fourth pixels PX4 respectively disposed in the second area AA2 to the fourth area AA4 may be arranged in the same arrangement structure as that of the first pixels PX1 disposed in the first area AA1. The pixels arranged in each of the first area AA1 to the fourth area AA4 may have the same arrangement structure, and only the shape of the pixels and direction in which the pixels extend may be different from each other.

The second area AA2 may include the second pixels PX2. The second pixels PX2 may include a second-first pixel PX2-B emitting the first color light, a second-second pixel PX2-G emitting the second color light, and a second-third pixel PX2-R emitting the third color light. The second pixels PX2 may have the same arrangement structure as the arrangement structure of the first pixels PX1 in the first area AA1.

The third area AA3 may include the third pixels PX3. The third pixels PX3 may include a third-first pixel PX3-B emitting the first color light, a third-second pixel PX3-G emitting the second color light, and a third-third pixel PX3-R emitting the third color light. The third pixels PX3 may have the same arrangement structure as the arrangement structure of the first pixels PX1 in the first area AA1.

The fourth area AA4 may include the fourth pixels PX4. The fourth pixels PX4 may include a fourth-first pixel PX4-B emitting the first color light, a fourth-second pixel PX4-G emitting the second color light, and a fourth-third pixel PX4-R emitting the third color light. The fourth pixels PX4 may have the same arrangement structure as the arrangement structure of the first pixels PX1 in the first area AA1.

An aperture ratio of the pixels having the same color in the first area AA1 to the fourth area AA4 may be the same. That is, the first-first pixel PX1-B, the second-first pixel PX2-B, the third-first pixel PX3-B, and the fourth-first pixel PX4-B, which emit the first color light, may have substantially the same size when viewed in the plane. The first-second pixel PX1-G, the second-second pixel PX2-G, the third-second pixel PX3-G, and the fourth-second pixel PX4-G, which emit the second color light, may have substantially the same size when viewed in the plane. The first-third pixel PX1-R, the second-third pixel PX2-R, the third-third pixel PX3-R, and the fourth-third pixel PX4-R, which emit the third color light, may have substantially the same size when viewed in the plane.

Meanwhile, in the present disclosure, the expression “Components are substantially aligned with each other.” or the expression “Components have substantially the same size.” means not only a case where a position in the plane of one component completely coincides with a position in the plane of another component or a case where the components have physically the same size, but also a case where the components are aligned with each other or the components have the same size within fabrication tolerances that commonly occur in the manufacturing process despite being identical in design.

FIG. 6A is a plan view of structures of pixels according to an embodiment of the present disclosure. In more detail, FIG. 6A is an enlarged plan view of an area AA1-a of FIG. 5.

Referring to FIG. 6A, the first-first pixel PX1-B may have an elliptical shape with a major axis LAX1-B and a minor axis SAX1-B. The first-second pixel PX1-G may have an elliptical shape with a major axis LAX1-G and a minor axis SAX1-G. The first-third pixel PX1-R may have an elliptical shape with a major axis LAX1-R and a minor axis SAX1-R. Each of the first-first pixel PX1-B, the first-second pixel PX1-G, and the first-third pixel PX1-R may have a first eccentricity value. The first eccentricity value may be equal to or greater than about 0.8 and equal to or smaller than about 1.0. The first eccentricity will be described with reference to FIGS. 6A and 6B.

In the present disclosure, an eccentricity K of an ellipse may be defined as

$$K = \sqrt{1 - \frac{R {min}^{2}}{R {max}^{2}}} .$$

In this case, Rmax denotes a radius in a major axis direction of the elliptical shape, and Rmin denotes a radius in a minor axis direction of the elliptical shape. The eccentricity may have a value from 0 to 1. As the eccentricity approaches 0, the elliptical shape may become more and more like a round circle, and as the eccentricity approaches 1, a difference in length between the major axis and the minor axis of the elliptical shape may increase. As the eccentricity of the elliptical shape approaches 1, the length of the major axis becomes longer.

The first-first pixel PX1-B may have a size greater than a size of the first-second pixel PX1-G and a size of the first-third pixel PX1-R when viewed in the plane. The size of the first-third pixel PX1-R may be greater than the size of the first-second pixel PX1-G when viewed in the plane.

A direction in which the major axis LAX1-B of the first-first pixel PX1-B extends may be the first direction DR1. Angles θLG1 and θLG2 between an extension direction of the major axis LAX1-G of the first-second pixel PX1-G and a horizontal line HL extending in the first direction DR1 may be about 40 degrees or more and about 50 degrees or less or may be about 130 degrees or more or about 140 degrees or less. The angles θLG1 and θLG2 between the extension direction of the major axis LAX1-G of the first-second pixel PX1-G and the horizontal line HL extending in the first direction DR1 may be about 45 degrees or about 135 degrees.

An angle (hereinafter, referred to as a first major axis angle) between the extension direction of the major axis LAX1-B of the first-first pixel PX1-B and the extension direction of the major axis LAX1-G of the first-second pixel PX1-G closest to the first-first pixel PX1-B may be about 40 degrees or more and about 50 degrees or less. For example, the first major axis angle may be about 45 degrees.

A minimum distance ML1 (hereinafter, referred to as a first pixel minimum separation distance) between two pixels adjacent to each other among the first-first pixel PX1-B, the first-second pixel PX1-G, and the first-third pixel PX1-R of each of the first pixels PX1 may be about 18/m. In a case where the first pixel minimum separation distance ML1 is smaller than about 18 μm and a mask is misaligned during a deposition process of each pixel, portions of the first-first pixel PX1-B, the first-second pixel PX1-G, and the first-third pixel PX1-R may overlap each other. In the case where the first pixel minimum separation distance ML1 is about 18 μm or more, the first-first pixel PX1-B, the first-second pixel PX1-G, and the first-third pixel PX1-R may be prevented from overlapping each other.

If the angle between the first major axes of adjacent pixels are aligned parallel (or perpendicular, depending on the position) to each other, the first pixel minimum separation distance ML1 may decrease. FIG. 6B depicts a case where major axes LAX2-B and LAX2-G (refer to FIG. 6B) are aligned either parallel or perpendicular to each other. Focusing on the second-second pixel PX2-G that is to the upper right of the second-third pixel PX2-B near the center area of area AA2-a, the major axes LAX2-B and LAX2-G are parallel. Focusing on the second-second pixel PX2-G that is to the lower right of the second-third pixel PX2-B near the center area of area AA2-a, the major axes LAX2-B and LAX2-G are perpendicular. In this arrangement, a second pixel minimum separation distance ML2 (refer to FIG. 6B) between the adjacent pixels may be short, possibly below the desired 18 μm. In the case of FIG. 6B, the second pixel minimum separation distance ML2 may be achieved by adjusting the eccentricity of the ellipse down, so that the length of each of the major axes LAX2-B and LAX2-G (refer to FIG. 6B) may decrease. This way, the second pixel minimum separation distance ML2 (refer to FIG. 6B) may be made to be substantially the same as the first pixel minimum separation distance ML1 of FIG. 6A.

That is, in the case where the angle between the extension direction of the major axis LAX1-B of the first-first pixel PX1-B and the extension direction of the major axis LAX1-G of the first-second pixel PX1-G nearest to the first-first pixel PX1-B increases, the first pixel minimum separation distance ML1 is less likely to decrease. Accordingly, the first eccentricity may increase to shorten the first pixel minimum separation distance ML1. In the case where the angle between the extension direction of the major axis LAX2-B of the second-first pixel PX2-B and the extension direction of the major axis LAX2-G of the second-second pixel PX2-G nearest to the second-first pixel PX2-B decreases (i.e., they're becoming closer to parallel), the first pixel minimum separation distance ML1 is more likely to decrease. Accordingly, the first eccentricity may decrease. The above descriptions may be equally applied to a second eccentricity of the second pixels PX2.

FIG. 6B is a plan view of structures of pixels according to an embodiment of the present disclosure. In more detail, FIG. 6B is an enlarged plan view of an area AA2-a of FIG. 5.

Referring to FIG. 6B, the second-first pixel PX2-B may have the elliptical shape with the major axis LAX2-B and a minor axis SAX2-B. The second-second pixel PX2-G may have the elliptical shape with the major axis LAX2-G and a minor axis SAX2-G. The second-third pixel PX2-R may have the elliptical shape with a major axis LAX2-R and a minor axis SAX2-R. Each of the second-first pixel PX2-B, the second-second pixel PX2-G, and the second-third pixel PX2-R may have a second eccentricity value. The value of second eccentricity may be smaller than the value of first eccentricity of FIG. 6A. The second eccentricity may be equal to or smaller than about 0.6.

The second-first pixel PX2-B may have a size greater than a size of the second-second pixel PX2-G and a size of the second-third pixel PX2-R when viewed in the plane. The size of the second-third pixel PX2-R may be greater than the size of the second-second pixel PX2-G when viewed in the plane.

An angle θLB between an extension direction of the major axis LAX2-B of the second-first pixel PX2-B and a horizontal line HL may be about 40 degrees or more and about 50 degrees or less. For example, the angle θLB between the extension direction of the major axis LAX2-B of the second-first pixel PX2-B and the horizontal line HL may be about 45 degrees. Angles θLG1 and θLG2 between an extension direction of the major axis LAX2-G of the second-second pixel PX2-G and the horizontal line HL may be about 40 degrees or more and about 50 degrees or less or may be about 130 degrees or more and about 140 degrees or less. For example, the angles θLG1 and θLG2 between the extension direction of the major axis LAX2-G of the second-second pixel PX2-G and the horizontal line HL may be about 45 degrees or about 135 degrees.

An angle (hereinafter, referred to as a second major axis angle) between the extension direction of the major axis LAX2-B of the second-first pixel PX2-B and the extension direction of the major axis LAX2-G of the second-second pixel PX2-G nearest to the second-first pixel PX2-B may be about 0 degrees.

The second pixel separation minimum distance ML2 (hereinafter, referred to as a second pixel minimum separation distance) between two pixels adjacent to each other among the second-first pixel PX2-B, the second-second pixel PX2-G, and the second-third pixel PX2-R of each of the second pixels PX2 may be equal to or greater than about 18/m.

Referring to FIGS. 6A and 6B, the first major axis angle of the first area AA1 may be about 45 degrees, and the second major axis angle of the second area AA2 may be about 0 degrees. The second major axis angle may be closer to 0 degrees than the first major axis angle. In this case, the second eccentricity may be adjusted to have a lower value than the first eccentricity. In the case of FIG. 6B, the major axis LAX2-B of the second-first pixel PX2-B and the major axis LAX2-G of the second-second pixel PX2-G adjacent to the second-first pixel PX2-B are parallel. Thus, one end of the major axis LAX2-B of the second-first pixel PX2-B and one end of the major axis LAX2-G of the second-second pixel PX2-G may become closer to each other.

If the second pixels PX2 were arranged as shown in FIG. 6B but had the eccentricity of the first pixels PX1 in FIG. 6A, the second pixel minimum separation distance ML2 would become too short. To maintain the predetermined second pixel minimum separation distance ML2, the eccentricity of each of the second pixels PX2 may be lowered to reduce the length of the major axes LAS2-B, LAX2-G, and LAX2-R.

An average of the first eccentricity and the second eccentricity may be equal to or greater than about 0.6. The average of the first eccentricity and the second eccentricity may be about 0.65.

FIG. 6C is a plan view of structures of pixels according to embodiments of the present disclosure. In more detail, FIG. 6C is an enlarged plan view of an area AA3-a of FIG. 5.

Referring to FIG. 6C, the third-first pixel PX3-B may have an elliptical shape with a major axis LAX3-B and a minor axis SAX3-B. The third-second pixel PX3-G may have an elliptical shape with a major axis LAX3-G and a minor axis SAX3-G. The third-third pixel PX3-R may have an elliptical shape with a major axis LAX3-R and a minor axis SAX3-R. Each of the third-first pixel PX3-B, the third-second pixel PX3-G, and the third-third pixel PX3-R may have a third eccentricity value. The value of the third eccentricity may be equal to or greater than about 0.8 and smaller than about 1.0. In the case of the third pixels PX3, the major axes LAX3-B, LAX3-G, and LAX3-R may not be aligned with each other in parallel relation. Due to this arrangement, similarly to the first pixels PX1 (refer to FIG. 6A), the pixel minimum separation distance is likely to be long in the third pixels PX3. Thus, the eccentricity value may be raised to shorten the distance.

The third-first pixel PX3-B may have a size greater than a size of the third-second pixel PX3-G and a size of the third-third pixel PX3-R when viewed in the plane. The size of the third-third pixel PX3-R may be greater than the size of the third-second pixel PX3-G when viewed in the plane.

An angle θLB between an extension direction of the major axis LAX3-B of the third-first pixel PX3-B and a horizontal line HL may be about 80 degrees or more and about 100. For example, the angle θLB between the extension direction of the major axis LAX3-B of the third-first pixel PX3-B and the horizontal line HL may be about 90 degrees. Angles θLG1 and θLG2 between an extension direction of the major axis LAX3-G of the third-second pixel PX3-G and the horizontal line HL may be about 40 degrees or more and about 50 degrees or less or may be about 130 degrees or more and about 140 degrees or less. For example, the angles θLG1 and θLG2 between the extension direction of the major axis LAX3-G of the third-second pixel PX3-G and the horizontal line HL may be about 45 degrees or about 135 degrees.

An angle (hereinafter, referred to as a third major axis angle) between the extension direction of the major axis LAX3-B of the third-first pixel PX3-B and the extension direction of the major axis LAX3-G of the third-second pixel PX3-G adjacent to the third-first pixel PX3-B may be about 40 degrees or more and about 50 degrees or less. The third major axis angle may be about 45 degrees.

A minimum distance ML3 (hereinafter, referred to as a third pixel minimum separation distance) between two pixels adjacent to each other among the third-first pixel PX3-B, the third-second pixel PX3-G, and the third-third pixel PX3-R of each of the third pixels PX3 may be about 18/m.

FIG. 6D is a plan view of structures of pixels according to an embodiment of the present disclosure. In more detail, FIG. 6D is an enlarged plan view of an area AA4-a of FIG. 5.

Referring to FIG. 6D, the fourth-first pixel PX4-B may have an elliptical shape with a major axis LAX4-B and a minor axis SAX4-B. The fourth-second pixel PX4-G may have an elliptical shape with a major axis LAX4-G and a minor axis SAX4-G. The fourth-third pixel PX4-R may have an elliptical shape with a major axis LAX4-R and a minor axis SAX4-R. Each of the fourth-first pixel PX4-B, the fourth-second pixel PX4-G, and the fourth-third pixel PX4-R may have a fourth eccentricity value. The value of the fourth eccentricity may be equal to or smaller than about 0.6. In the case of the fourth pixels PX4, the major axes LAX4-B and LAX4-G may be parallel (or perpendicular, depending on which fourth-second pixel PX4-G). Due to this parallel alignment of the major axes LAX4-B and LAX4-G, similarly to the second pixels PX2 (refer to FIG. 6B), the pixel minimum separation distance ML4 is likely to be short in the fourth pixels PX4. Hence, so that the fourth eccentricity value may be lowered to increase the distance.

The fourth-first pixel PX4-B may have a size greater than a size of the fourth-second pixel PX4-G and a size of the fourth-third pixel PX4-R when viewed in the plane. The size of the fourth-third pixel PX4-R may be greater than the size of the fourth-second pixel PX4-G.

An angle θLB between an extension direction of the major axis LAX4-B of the fourth-first pixel PX4-B and a horizontal line HL may be about 130 degrees or more and about 140 degrees or less. For example, the angle θLB between the extension direction of the major axis LAX4-B of the fourth-first pixel PX4-B and the horizontal line HL may be about 135 degrees. Angles θLG1 and θLG2 between an extension direction of the major axis LAX4-G of the fourth-second pixel PX4-G and the horizontal line HL may be about 40 degrees or more and about 50 degrees or less or may be about 130 degrees or more and about 140 degrees or less. For example, the angles θLG1 and θLG2 between the extension direction of the major axis LAX4-G of the fourth-second pixel PX4-G and the horizontal line HL may be about 45 degrees or about 135 degrees.

An angle (hereinafter, referred to as a fourth major axis angle) between the extension direction of the major axis LAX4-B of the fourth-first pixel PX4-B and the extension direction of the major axis LAX4-G of the fourth-second pixel PX4-G nearest to the fourth-first pixel PX4-B may be about 0 degrees. The fourth major axis angle may be about 0 degrees.

A minimum distance ML4 (hereinafter, referred to as a fourth pixel minimum separation distance) between two pixels adjacent to each other among the fourth-first pixel PX4-B, the fourth-second pixel PX4-G, and the fourth-third pixel PX4-R of each of the fourth pixels PX4 may be equal to or greater than about 18/m.

Referring to FIGS. 6A to 6D, the first, second, third, and fourth pixel minimum separation distances ML1, ML2, ML3, and ML4 may be substantially the same as each other. The first, second, third, and fourth pixel minimum separation distances ML1, ML2, ML3, and ML4 may be kept substantially the same by varying the eccentricity according to the extension direction of the major axis in each of the first, second, third, and fourth areas AA1, AA2, AA3, and AA4.

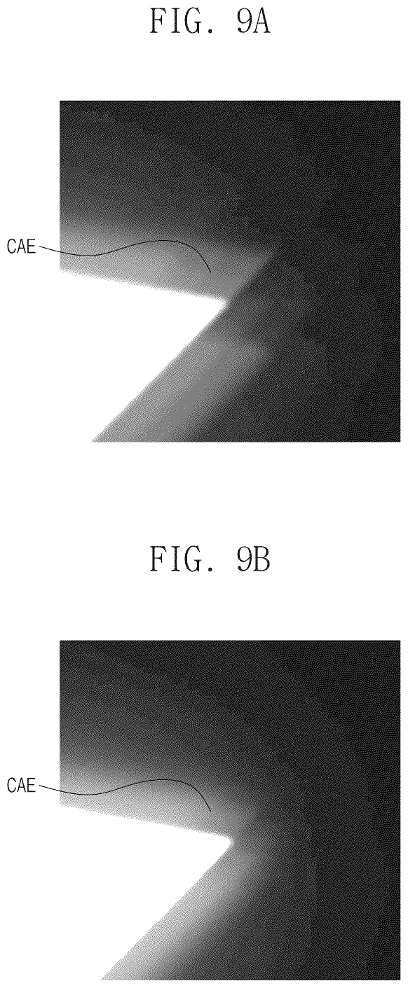

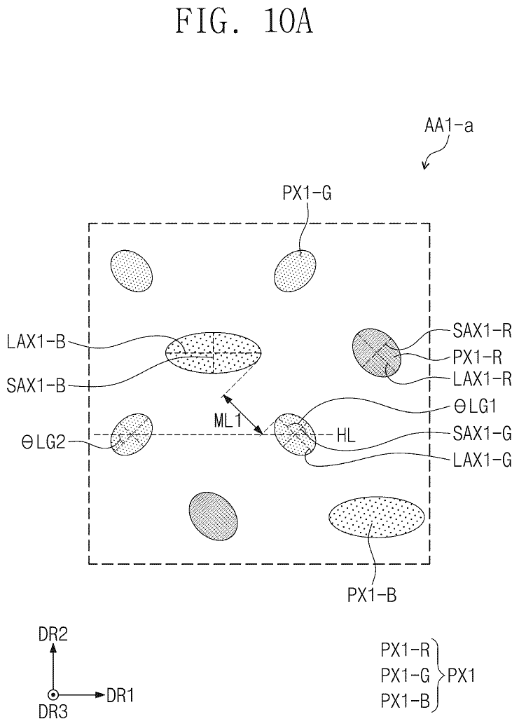

In addition, the pixels PX (refer to FIG. 3) of the display area DP-DA (refer to FIG. 3) may be irregularly arranged by varying the shape and arrangement angle of the pixels arranged in each of the first, second, third, and fourth areas AA1, AA2, AA3, and AA4. Multiple images due to a reflection of the external light may be reduced more when the pixels PX (refer to FIG. 3) are arranged irregularly than when the pixels PX (refer to FIG. 3) are arranged regularly. This will be described below with reference to FIGS. 9A and 9B.

An average of the first to fourth eccentricities may be equal to or greater than about 0.6. The average of the first to fourth eccentricities may be about 0.65.

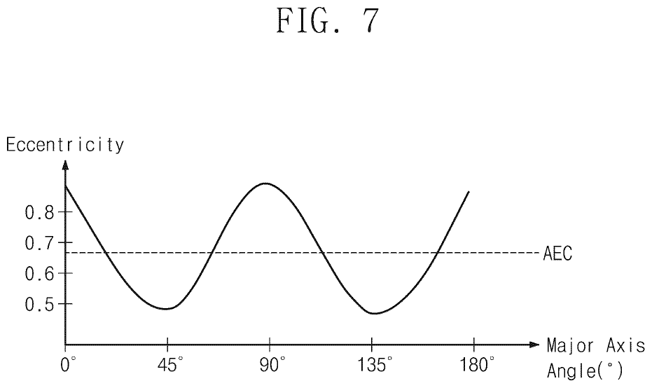

FIG. 7 is a graph showing a relationship between the angle of the major axis and the eccentricity according to an embodiment of the present disclosure. In FIG. 7, the major axis angle may indicate the angle between the major axes LAX1-B, LAX2-B, LAX3-B, and LAX4-B of the respective pixels PX1-B, PX2-B, PX3-B, and PX4-B emitting the first color light in FIGS. 6A to 6D and the horizontal line HL.

Referring to FIGS. 6A to 6D and 7, the eccentricity values of the pixels may be varied as the major axis angle is changed. An arrangement of the pixels when the major axis angle is zero (0) degrees may be substantially the same as the arrangement of the first pixels PX1 of the first area AA1 shown in FIG. 6A. An arrangement of the pixels when the major axis angle is 45 degrees may be substantially the same as the arrangement of the second pixels PX2 of the second area AA2 shown in FIG. 6B. An arrangement of the pixels when the major axis angle is 90 degrees may be substantially the same as the arrangement of the third pixels PX3 of the third area AA3 shown in FIG. 6C. An arrangement of the pixels when the major axis angle is 135 degrees may be substantially the same as the arrangement of the fourth pixels PX4 of the fourth area AA4 shown in FIG. 6D.

As the major axis angle approaches about 45 degrees or about 135 degrees, the major axes LAX1-B, LAX2-B, LAX3-B, and LAX4-B of the pixels PX1-B, PX2-B, PX3-B, and PX4-B emitting the first color light and the major axes of the pixels adjacent to the pixels PX1-B, PX2-B, PX3-B, and PX4-B emitting the first color light may be extend parallel to one another. With this parallel-axis arrangement, the minimum separation distance between the pixels is likely to be short as described above. To lengthen the minimum separation distance, the eccentricity value may be adjusted down to, effectively reducing the length of the major axis. In the case where the major axis angle is about 45 degrees or about 135 degrees, the eccentricity value may be equal to or smaller than about 0.6.

In the case where the major axis angle approaches zero (0) degrees or 90 degrees, the major axes LAX1-B, LAX2-B, LAX3-B, and LAX4-B of the respective pixels PX1-B, PX2-B, PX3-B, and PX4-B emitting the first color light and the major axes of the pixels adjacent to the pixels PX1-B, PX2-B, PX3-B, and PX4-B emitting the first color light may not extend in parallel directions. In this case, the minimum separation distance between the pixels is likely to be long, as described above. Hence, the length of the major axis could be made longer by adjusting the eccentricity value higher without going below the minimum separation distance. In the case where the major axis angle is zero (0) degrees or 90 degrees, the eccentricity value may be equal to or greater than about 0.8 and smaller than about 1. The average eccentricity value AEC of the entire pixels may be about 0.65.

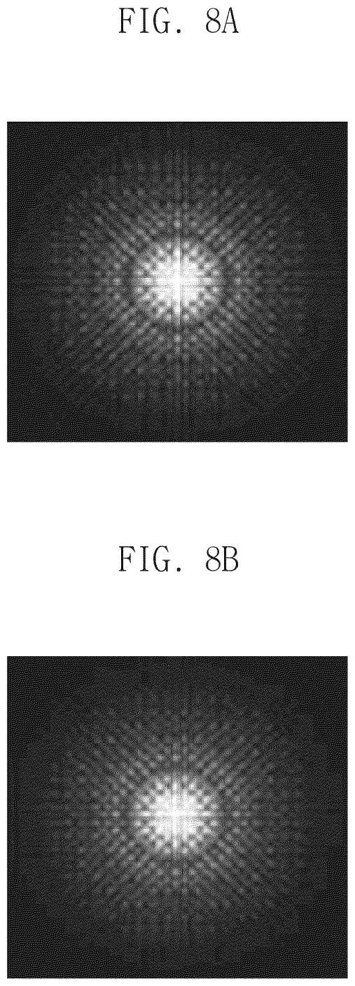

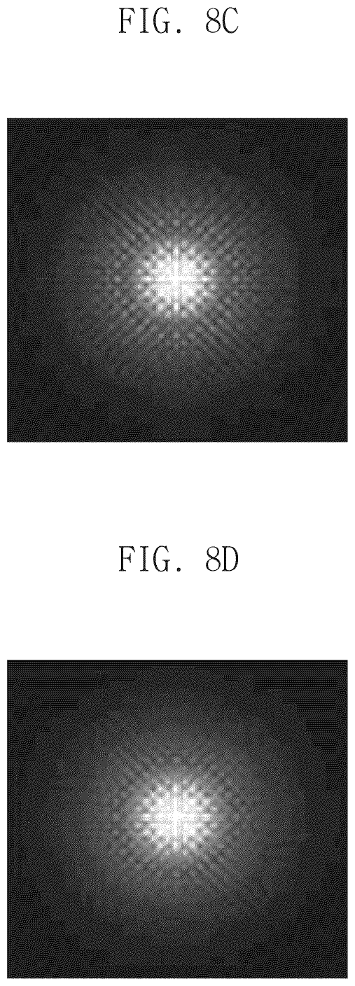

FIGS. 8A to 8D are views of reflection characteristics according to the eccentricity of the pixel. In more detail, FIG. 8A is a view showing an image of the external light reflected from the display panel DP (refer to FIG. 2) when the pixel has a circular shape with an eccentricity value of about 0. FIG. 8B is a view showing an image of the external light reflected from the display panel DP (refer to FIG. 2) when the pixel has an elliptical shape with an eccentricity value of about 0.5. FIG. 8C is a view showing an image of the external light reflected from the display panel DP (refer to FIG. 2) when the pixel has an elliptical shape with an eccentricity value of about 0.7. FIG. 8D is a view showing an image of the external light reflected from the display panel DP (refer to FIG. 2) when the pixel has an elliptical shape with an eccentricity value of about 0.8.

Referring to FIGS. 8A to 8D, as the eccentricity value of the pixel increases, a color distinction of the image (hereinafter, referred to as a reflected image) of the external light reflected from the display panel DP (refer to FIG. 2) may become unclear. Accordingly, likelihood of a user viewing reflected images may be lowered, and the reflection characteristics of the display device may therefore be improved. That is, as the average eccentricity value of the pixel increases, the reflection characteristics may improve.

FIGS. 9A and 9B are views of reflection characteristics according to the eccentricity of the pixel. In more detail, FIG. 9A is a view of a double image CAE of the display panel DP (refer to FIG. 2) including pixels with fixed eccentricity and direction. FIG. 9B is a view of a double image CAE of the display panel DP (refer to FIG. 2) including pixels whose eccentricity and direction are varied, such as the pixels arranged in the first, second, third, and fourth areas AA1, AA2, AA3, and AA4 (refer to FIG. 5) of FIG. 5.

FIG. 9A depicts the colors viewed with pixels in regular arrangement. FIG. 9B depicts the colors viewed with pixels in irregular arrangement. Referring to FIGS. 9A and 9B, a color distinction of a double image CAE may become blurred when the pixels are irregularly arranged (refer to FIG. 9B) than when the pixels are regularly arranged (refer to FIG. 9A). Accordingly, likelihood of the user viewing double image CAE may be lowered, and thus, characteristics of the double image CAE may improve.

Referring to FIGS. 8A to 8D, 9A, and 9B, as the average eccentricity value of the pixels increase, the reflection characteristics may be improved. In addition, an irregular pixel arrangement improves the characteristics of the double image CAE. According to the present disclosure, the pixels are arranged irregularly by varying the eccentricity and direction thereof depending on areas of the display panel (refer to FIG. 4), and thus, the characteristics of the double image CAE may improve. In addition, according to the present disclosure, since the average eccentricity increases by varying the eccentricity according to the extension direction of the major axis, the reflection characteristics may be improved.

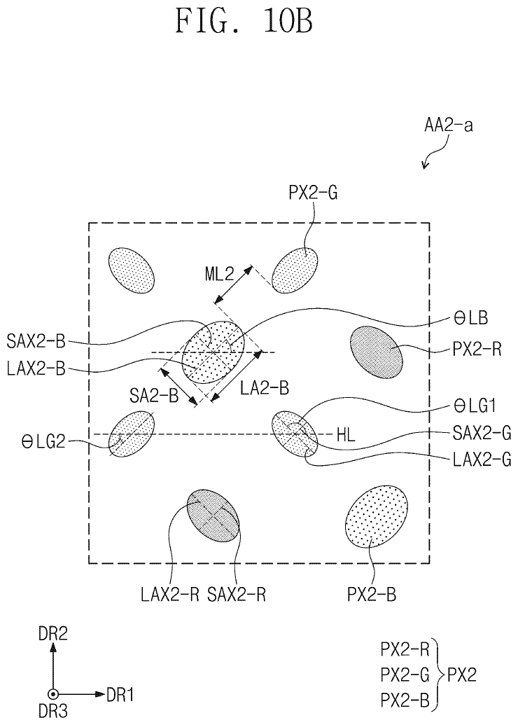

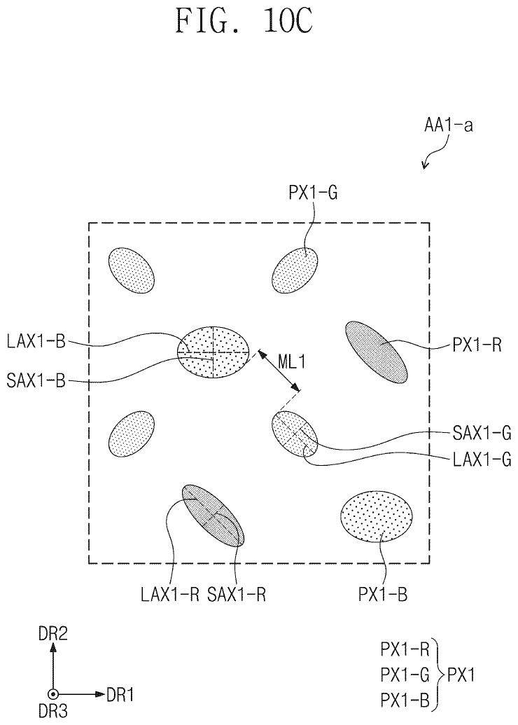

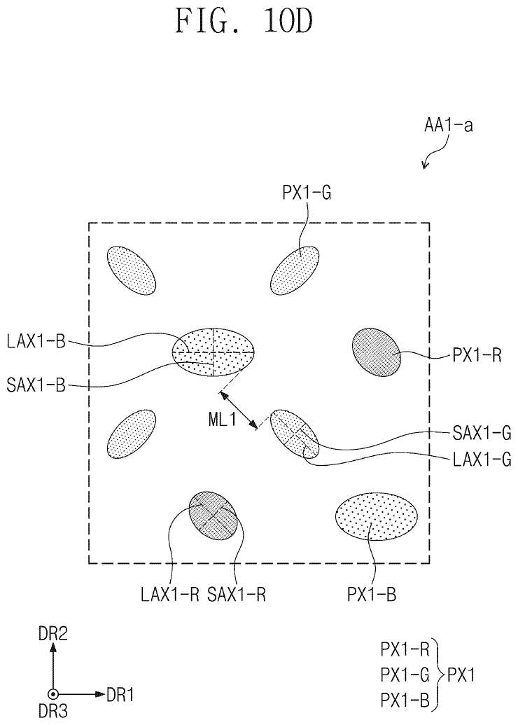

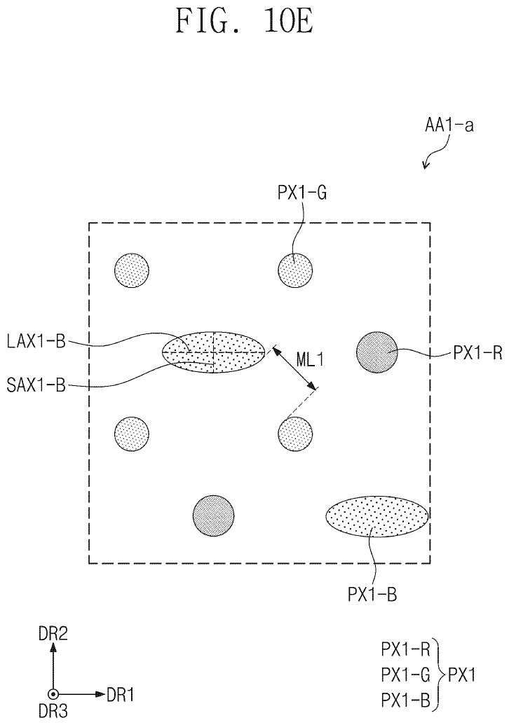

FIG. 10A is a plan view of structures of pixels according to an embodiment of the present disclosure. FIG. 10B is a plan view of structures of pixels according to an embodiment of the present disclosure. In more detail, FIG. 10A is an enlarged plan view of a portion of the first area AA1 (refer to FIG. 5) according to the embodiment of the present disclosure. FIG. 10B is an enlarged plan view of a portion of the second area AA2 (refer to FIG. 5) according to the embodiment of the present disclosure. Hereinafter, descriptions of the same configurations as those described above will be omitted.

Referring to FIG. 10A, a first-first pixel PX1-B may have an elliptical shape with a first-first eccentricity value. A first-second pixel PX1-G may have an elliptical shape with a first-second eccentricity value. A first-third pixel PX1-R may have an elliptical shape with a first-third eccentricity value. The value of first-first eccentricity may be different from at least one of the value of the first-second eccentricity and the value of the first-third eccentricity. An average value of the first-first eccentricity, the first-second eccentricity, and the first-third eccentricity may be equal to or greater than about 0.6. The value of the first-first eccentricity may be greater than that of the first-second eccentricity and the first-third eccentricity. The value of first-second eccentricity may be substantially the same as the value of first-third eccentricity. For example, the value of the first-first eccentricity may be about 0.8, and the value of the first-second eccentricity and the first-third eccentricity may be about 0.6. However, the first-first eccentricity, the first-second eccentricity, and the first-third eccentricity may have different values from each other. As described above, a reflection color of the display panel (refer to FIG. 4) may be varied by applying different eccentricity depending on the colors of the pixels.

For example, in a case where the reflection color of a first color is relatively high in the reflected image of the external light reflected from the display panel DP (refer to FIG. 2), the reflection color of the first color may decrease by increasing the first-first eccentricity value. In addition, the reflection color of a second color and a third color may increase by decreasing the first-second eccentricity value and the first-third eccentricity value. Accordingly, the color distinction of the first to third colors of the reflected image of the external light may become unclear, the visibility of the user with respect to the reflected image may decrease, and as a result, the reflection characteristics may be improved.

In addition, the pixels may be irregularly arranged by applying the different eccentricity values depending on the colors of the pixels, and thus, the characteristics of the double image CAE may be improved.

Referring to FIG. 10B, a major axis LAX2-B of a second-first pixel PX2-B may be aligned with a major axis LAX2-G of a second-second pixel PX2-G in parallel relation. In this case, when the eccentricity value of the second-first pixel PX2-B is set to be high as shown in FIG. 10A, the second pixel minimum separation distance ML2 may become two small. Accordingly, an eccentricity value of the second-first pixel PX2-B in a second area AA2 of FIG. 10B may be adjusted down to be lower than the eccentricity value of a first-first pixel PX1-B in the first area AA1 of FIG. 10A.

The second-first pixel PX2-B, the second-second pixel PX2-G, and a second-third pixel PX2-R may have elliptical shapes with the same second eccentricity value. As described above, when the different eccentricities are applied to first pixels PX1 (refer to FIG. 10A) according to colors of the first pixels PX1 and a fixed eccentricity is applied to second pixels PX2, the pixels may be irregularly arranged as a whole. Accordingly, the characteristics of the double image CAE may be improved.

FIGS. 10C and 10D are plan views of structures of pixels according to an embodiment of the present disclosure. In more detail, FIGS. 10C and 10D are enlarged plan views of a portion of the first area AA1 (refer to FIG. 5) according to embodiments of the present disclosure.

Referring to FIG. 10C, a first-first pixel PX1-B may have an elliptical shape with a first-first eccentricity value. A first-second pixel PX1-G may have an elliptical shape with a first-second eccentricity value. A first-third pixel PX1-R may have an elliptical shape with a first-third eccentricity value. The first-third eccentricity value may be different from at least one of the first-first eccentricity value and the first-second eccentricity value. For example, the first-third eccentricity value may be about 0.8, and the first-first eccentricity value and the first-second eccentricity value may be about 0.6.

In a case where a reflection color of a second color is relatively high in the reflected image of the external light reflected from the display panel DP (refer to FIG. 2), the reflection color of the second color may decrease by increasing the value of the first-second eccentricity. In addition, a reflection color of a first color and a third color may increase by decreasing the values of the first-first eccentricity and the first-third eccentricity. Accordingly, the color distinction of the first to third colors of the reflected image of the external light may become unclear, the likelihood of the user viewing the reflected image may decrease, and as a result, the reflection characteristics may be improved.

Referring to FIG. 10D, a first-first pixel PX1-B may have an elliptical shape with a first-first eccentricity value. A first-second pixel PX1-G may have an elliptical shape with a first-second eccentricity value. A first-third pixel PX1-R may have an elliptical shape with a first-third eccentricity value. The value of the first-second eccentricity may be different from at least one of the value of the first-first eccentricity and the value of the first-third eccentricity. For example, the first-second eccentricity value may be about 0.8, and the first-first eccentricity value and the first-third eccentricity value may be about 0.6.

In a case where a reflection color of a third color is relatively high in the reflected image of the external light reflected from the display panel DP (refer to FIG. 2), the reflection color of the third color may decrease by increasing the first-third eccentricity value. In addition, a reflection color of a first color and a second color may increase by decreasing the first-first eccentricity value and the first-second eccentricity value. Accordingly, the color distinction of the first to third colors of the reflected image of the external light may become unclear, the likelihood of the user seeing the reflected image may decrease, and as a result, the reflection characteristics may be improved.

FIG. 10E is a plan view of structures of pixels according to an embodiment of the present disclosure. In more detail, FIG. 10E is an enlarged plan view of a portion of the first area AA1 (refer to FIG. 5) according to the embodiment of the present disclosure.

Referring to FIG. 10E, a first-first pixel PX1-B may have an elliptical shape with a first-first eccentricity value. A first-second pixel PX1-G and a first-third pixel PX1-R may have a circular shape. FIG. 10E shows the structure in which only the first-first pixel PX1-B has the elliptical shape, however, according to an embodiment, only the first-second pixel PX1-G or only the first-third pixel PX1-R may have an elliptical shape.

In a case where a reflection color of a first color is relatively high in the reflected image of the external light reflected from the display panel DP (refer to FIG. 2), the reflection color of the first color may decrease by setting only the first-first pixel to have the elliptical shape with the first-first eccentricity value. Since the first-second pixel and the first-third pixel have the eccentricity value of zero (0), the reflection color of the second color and the third color may increase.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims.

What is claimed is:

1. A display device comprising:
a display panel comprising a display area comprising a first area and a second area adjacent to the first area and a non-display area adjacent to the display area; and
an anti-reflective layer disposed on the display panel, wherein the first area comprises a plurality of first pixels, the second area comprises a plurality of second pixels, the first pixels comprise a first-first pixel emitting a first color light, a first-second pixel emitting a second color light, and a first-third pixel emitting a third color light, the second pixels comprise a second-first pixel emitting the first color light, a second-second pixel emitting the second color light, and a second-third pixel emitting the third color light, each of the first-first, first-second, and first-third pixels has an elliptical shape having a major axis, a minor axis, and a first eccentricity value, each of the second-first, second-second, and second-third pixels has an elliptical shape having a major axis, a minor axis, and a second eccentricity value that is lower than the first eccentricity value, and a second angle is closer to zero than a first angle,
wherein the first angle is an angle between a direction in which the major axis of the first-first pixel extends and a direction in which the major axis of the first-second pixel nearest to the first-first pixel extends, and the second angle is an angle between a direction in which the major axis of the second-first pixel extends and a direction in which the major axis of the second-second pixel nearest to the second-first pixel extends.

2. The display device of claim 1, wherein the first-first pixel has a size greater than a size of the first-second pixel and a size of the first-third pixel when viewed in a plane, and the second-first pixel has a size greater than a size of the second-second pixel and a size of the second-third pixel when viewed in the plane.

3. The display device of claim 1, wherein the first color light is a blue light, the second color light is a green light, and a third color light is a red light.

4. The display device of claim 1, wherein the first pixels comprise a first pixel row and a second pixel row, the first pixel row comprises the first-first pixel and the first-third pixel arranged in a first direction, and the second pixel row comprises the first-second pixel arranged in the first direction.

5. The display device of claim 1, wherein the second pixels comprise a first pixel row and a second pixel row, the first pixel row comprises the second-first pixel and the second-third pixel, which are arranged in a first direction, and the second pixel row comprises the second-second pixel arranged in the first direction.

6. The display device of claim 1, wherein the first angle is equal to or greater than about 40 degrees and equal to or smaller than about 50 degrees.

7. The display device of claim 1, wherein the second angle is about zero (0) degrees.

8. The display device of claim 1, wherein the first-first pixel and the second-first pixel have substantially a same size when viewed in a plane.

9. The display device of claim 1, wherein the anti-reflective layer comprises:
a color filter disposed on the display panel and overlapping the first pixels and the second pixels;
a light blocking pattern disposed on the display panel and preventing an external light from being reflected; and
a planarization layer covering the color filter and the light blocking pattern and providing a flat upper surface.

10. The display device of claim 1, wherein a minimum distance between two pixels adjacent to each other among the first-first, first-second, and first-third pixels of each of the first pixels is substantially equal to a minimum distance between two pixels adjacent to each other among the second-first, second-second, and second-third pixels of each of the second pixels.

11. The display device of claim 1, wherein a minimum distance between two pixels adjacent to each other among the first-first, first-second, and first-third pixels of each of the first pixels is equal to or greater than about 18 micrometers.

12. The display device of claim 1, wherein the first eccentricity value is equal to or greater than about 0.8 and smaller than about 1.

13. The display device of claim 1, wherein the second eccentricity value is equal to or smaller than about 0.6.

14. The display device of claim 1, wherein an average of the first eccentricity value and the second eccentricity value is equal to or greater than about 0.6.

15. A display device comprising:
a display panel comprising a display area comprising a plurality of pixels and a non-display area adjacent to the display area; and
an anti-reflective layer disposed on the display panel, wherein the pixels comprise a first pixel emitting a first color light and having an elliptical shape with a first eccentricity value, a second pixel emitting a second color light and having an elliptical shape with a second eccentricity value, and a third pixel emitting a third color light and having an elliptical shape with a third eccentricity value, and the first eccentricity value increases when an angle between a direction in which a major axis of the first pixel extends and a direction in which a major axis of the second pixel nearest to the first pixel extends increases.

16. The display device of claim 15, wherein the first eccentricity value, the second eccentricity value, and the third eccentricity value are substantially the same.

17. The display device of claim 15, wherein the first eccentricity value is different from at least one of the second eccentricity value and the third eccentricity value.

18. The display device of claim 15, wherein the first eccentricity value is greater than the second eccentricity value and the third eccentricity value, and the second eccentricity value and the third eccentricity value are substantially the same.

19. The display device of claim 15, wherein the first pixel has a size greater than a size of the second pixel and a size of the third pixel when viewed in a plane.

20. The display device of claim 15, wherein an average of the first eccentricity value, the second eccentricity value, and the third eccentricity value is equal to or greater than about 0.6.
